(19) United States
(12) Patent Application Publication
(10) Pub. No.: US 2026/0237890 A1
(43) Pub. Date: Aug. 13, 2026

(54) MAGNETIC TRANSPORT MOUNTING AND PROTECTIVE CASE FOR AN INTERNET COMMUNICATION TERMINAL

(71) Applicants: Mykola KALINICHENKO, Kyiv (UA); Anton SADYKOV, Kyiv (UA)

(72) Inventors: Mykola KALINICHENKO, Kyiv (UA); Anton SADYKOV, Kyiv (UA)

(21) Appl. No.: 19/539,410

(22) Filed: Feb. 13, 2026

Related U.S. Application Data
(60) Provisional application No. 63/757,817, filed on Feb. 13, 2025.

(51) Int. Cl. H01Q 1/32; F16M 11/04; H05K 5/02; H05K 7/20

(52) U.S. Cl. CPC H01Q 1/3275; F16M 11/041; H05K 5/0204; H05K 7/20727

(57) ABSTRACT

A magnetic transport mounting and protective housing for a satellite communication terminal having a protective housing that employs magnets to secure the housing to a vehicle.

### CROSS-REFERENCE TO RELATED APPLICATION

This application claims the benefit of priority date of U.S. Provisional Patent Application No. 63/757,817 filed on Feb. 13, 2025. The contents of this application is herein incorporated by reference in its entirety.

### FIELD OF THE INVENTION

The invention relates to a mounting assembly (box) for an internet terminal which can be placed on different vehicles. Furthermore, the invention belongs to the field of telecommunications equipment, namely to means of mounting, fastening and protecting satellite communication terminals on vehicles, as well as to the field of automotive accessories and mobile telecommunications systems for use while driving.

### BACKGROUND OF THE INVENTION

Transportation of powerful Internet terminals and ensuring uninterrupted communication while driving is a modern need. Internet terminals are exposed to negative environmental factors, so they should be protected and covered.

U.S. Pat. No. 11,990,688 B2 describes an antenna system mounted in a vehicle, which includes a radiator for transferring, through an upper opening, a signal which is applied through a lower opening; a coupling patch disposed on an upper substrate so as to be spaced apart from the upper opening by a predetermined interval so as to enable the coupling of the signal which has been transferred through the upper opening; and a first antenna connected to the coupling patch so as to make surface contact therewith, and comprising a shorting bar for connecting a ground layer of a lower substrate. Such an integrated solution is not easy enough to repair and replace and is limited to use in certain vehicles.

US Patent Application No. 2014/0132022 A1 discloses a roof box is provided for motor vehicles for forming a useful interior space. In order to obtain a roof box which is comfortable to handle by a user, offers the greatest possible storage space and simultaneously reduces vehicle noises and fuel consumption, the roof box includes the use of volume changing means for changing the volume of the interior space, the roof box being designed such that it can be integrated into the roof of a motor vehicle. This invention is quite bulky, requires a certain mounting surface, and creates significant air resistance.

Other references include standard or third-party transport mounts for satellite terminals, in particular: rigid brackets for stationary or semi-stationary installation; or magnetic car mounts without a protective housing and without movable supports.

However, existing mounts suffer from disadvantages including insufficient fastening stability on surfaces of complex geometry; lack of compensation for vibrations and dynamic loads during vehicle movement; increased risk of breakage or separation when driving at high speed; lack of an integrated protective housing for the satellite communication terminal; inability to quickly install and remove without additional tools; limited adaptation to different types of vehicles; and the need to drill holes in the vehicle, which implies fixed mounting.

It is an object of the invention to overcome these disadvantages.

### SUMMARY OF THE INVENTION

The claimed technical solution aims solving a technical problem, constituting a creation of a mounting assembly (box) suitable for different types and shapes of a surface of vehicles while creating minimal air resistance and allowing for an internet terminal.

According to a preferred embodiment of the invention, a mounting assembly (a box) for an internet terminal includes a first surface, a second surface bolted to the first surface forming a cavity between said surfaces, and a plurality of hinged rubber-coated magnets connected to the second surface and configured to change their distance from the second surface by moving along a thread.

In certain embodiments, a longitudinal projection of the second surface has the shape of a triangle.

In certain embodiments, a transverse projection of the second surface has the shape of a trapezoid.

In certain embodiments, the second surface comprising a hole for placement, fixation between the first and the second surfaces, and connection of an internet terminal.

In certain embodiments, the surfaces may be made of plastic.

In certain embodiments, the box may include a plurality of galvanized metal plates connected to the plurality of hinged rubber-coated magnets and configured to be installed on aluminum, plastic roofs, and roofs with panoramic glass of a vehicle.

In other embodiments, the invention is directed to a magnetic transport mounting and protective housing for a satellite communication terminal that has: a protective housing having an upper and a lower surface, as well as front and rear portions; four hinged supports rigidly connected to the housing in its corner regions; the hinged supports are divided into two pairs, wherein: a first pair of supports is arranged at the front portion of the housing and has a greater structural height relative to the mounting surface of the vehicle; a second pair of supports is arranged at the rear portion of the housing and has a smaller structural height relative to the mounting surface of the vehicle; the difference in height between the front and rear supports forms an inclination of the housing relative to the vehicle mounting surface, whereby the upper surface of the housing is positioned at a predetermined angle relative to said surface; and a neodymium magnet is secured to the lower part of each support and is housed in a rubberized casing.

In certain embodiments, each hinged support is configured to allow angular deflection and has a fixed structural inclination angle of 26 degrees, providing adaptation to surfaces of complex geometry.

In certain embodiments, the magnets are arranged such that all four supports simultaneously contact the mounting surface of the vehicle.

In certain embodiments, the housing is configured to accommodate a Starlink Mini terminal therein with fixation preventing displacement of the terminal during vehicle movement.

In certain embodiments, the protective housing is made of 3 mm thick ABS plastic.

In certain embodiments, the four hinged supports are made of stainless steel.

Other assemblies, systems, methods, apparatus, features, and advantages of the present invention will be apparent to one skilled in the art upon examination of the following figures and detailed description. Component parts shown in the drawings are not necessarily to scale, and may be exaggerated to better illustrate the important features of the present invention.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

FIG. 1 is a perspective view of a mounting assembly (box) for an internet terminal.

FIG. 2 is a side view showing inclination of the housing.

FIG. 3 is a top view of the mounting assembly;

FIG. 4 is a back view of the housing;

FIG. 5 is a detailed view of a hinged support member; and

FIG. 6 is an exploded view of the hinged support member with magnet;

### DETAILED DESCRIPTION

Certain embodiments commensurate in scope with the originally claimed subject matter are summarized below. These embodiments are not intended to limit the scope of the disclosure, but rather these embodiments are intended only to provide a brief summary of certain disclosed embodiments. Indeed, the present disclosure may encompass a variety of forms that may be similar to or different from the embodiments set forth below.

According to a preferred embodiment of the invention, a mounting assembly (a box) for an internet terminal includes a first surface, a second surface bolted to the first surface forming a cavity between said surfaces, and a plurality of hinged rubber-coated magnets connected to the second surface and configured to change their distance from the second surface by moving along a thread. A longitudinal projection of the second surface has the shape of a triangle. A transverse projection of the second surface has the shape of a trapezoid. The second surface comprising a hole for placement, fixation between the first and the second surfaces, and connection of an internet terminal. Said surfaces may optionally be made of plastic. The box may optionally include a plurality of galvanized metal plates connected to the plurality of hinged rubber-coated magnets and configured to be installed on aluminum, plastic roofs, and roofs with panoramic glass of a vehicle.

The shape of the second surface ensures high air flow performance. The plurality of hinged rubber-coated magnets ensures their reliable placement on surfaces of various shapes without damaging such surfaces. The invention can be applied to cars, buses, military transport, mobile homes, boats, agricultural machinery etc.

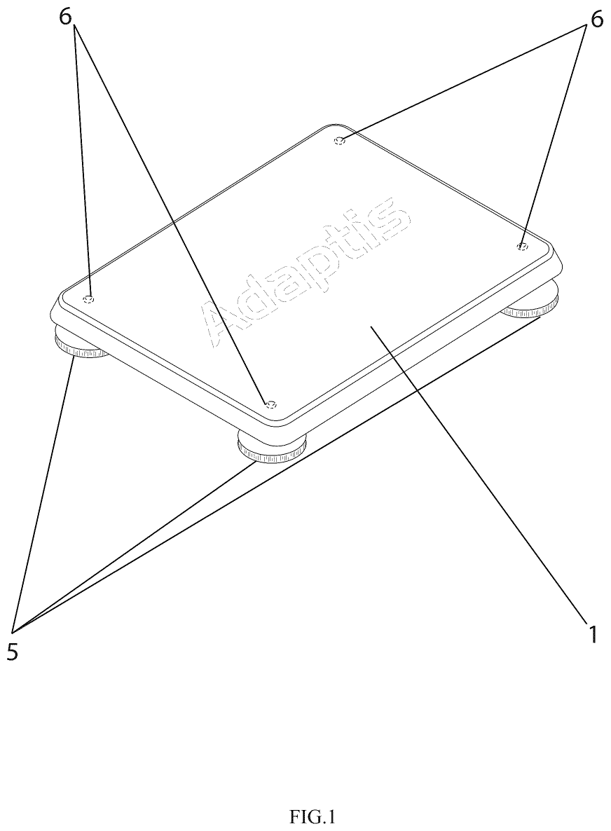

As shown in FIG. 1, the mounting assembly has a body 1 that includes two surfaces whereby the first and second surfaces are bolted together via bolts 6. The mounting assembly has a plurality of hinged rubber-coated magnets 5 which a connected to the second bottom lower surface.

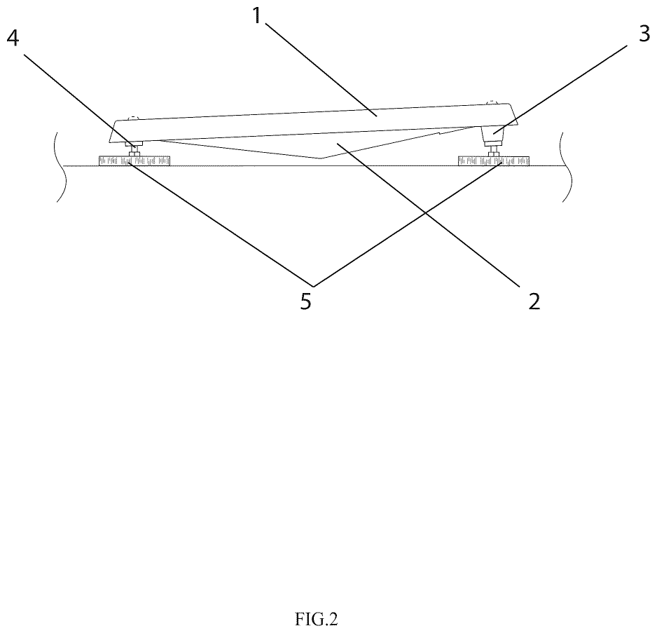

FIG. 2 is a side view of the mounting assembly showing the inclination of the housing. The rubber coated magnets 5 are connected to the cavity. The transverse projection 2 of the second surface is shown having the shape of a trapezoid. Furthermore, the magnets are shown at an incline such that connecting element 3 is larger than connecting element 4, thereby allowing an incline between one side of the mounting assembly.

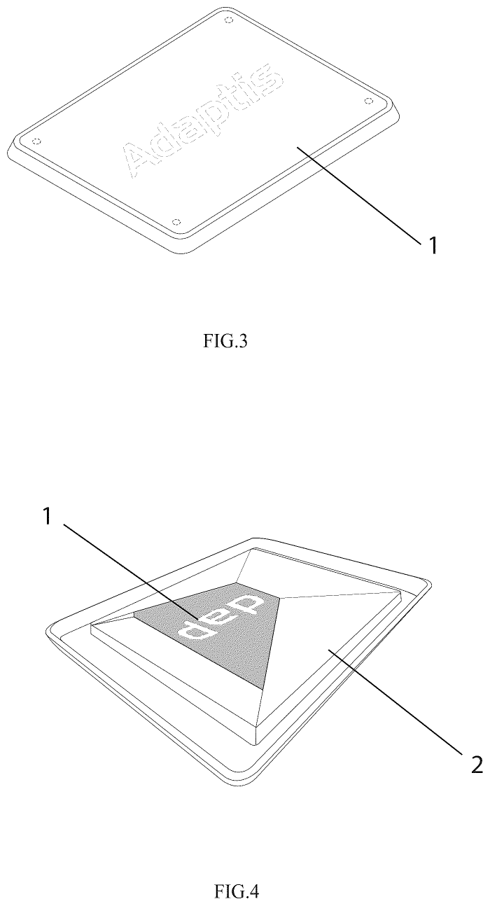

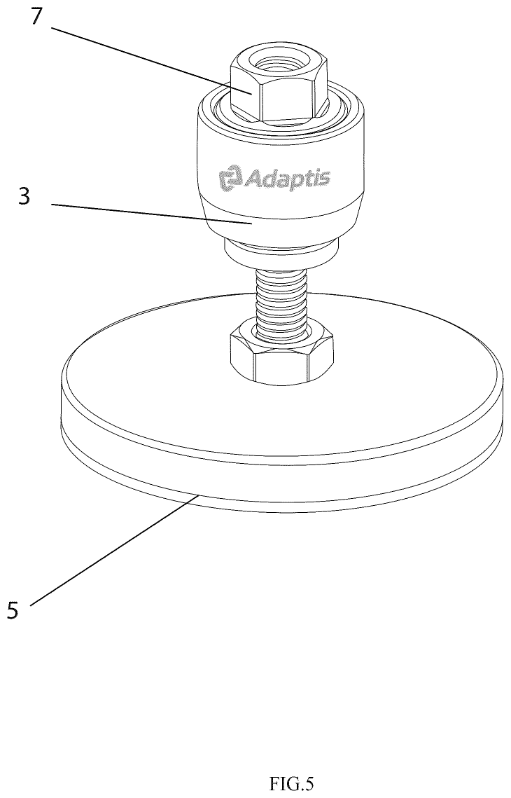

FIG. 3 a top view of the mounting assembly and FIG. 4 is a back view of the mounting assembly.

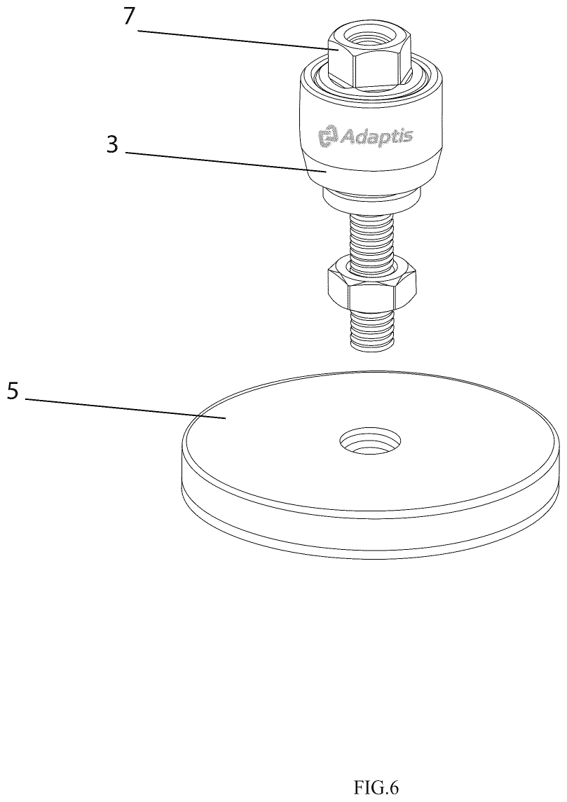

The bolt structure to connect plurality of hinged rubber-coated magnets 5 to the surface is shown in FIGS. 5 and 6. FIG. 5 shows a screw thread with nut element 7 and body 3 adapted to alter the distance of the second surface of the cavity sitting on the body 3.

The rubber-coated magnet 5 is shown connected to the thread element and a second nut is used to control the distance and thereby the incline mounting assembly.

### Technical Result

The claimed technical solution ensures achievement of the following technical result.

Manufacturing the protective housing from 3 mm thick ABS plastic provides a combination of mechanical strength and low weight of the housing, which reduces inertial loads acting on the device during vehicle movement, and also provides protection of the satellite communication terminal from atmospheric precipitation, ingress of dust, dirt, and mechanical debris that may occur during vehicle operation, in particular when driving on uneven road surfaces or off-road.

Providing the housing with four hinged supports divided into two pairs having different structural heights results in formation of an inclination of the housing relative to the vehicle mounting surface, whereby the upper surface of the housing is positioned at a predetermined angle relative to the direction of the oncoming airflow.

Such inclination of the housing ensures a change in the nature of airflow around the housing during vehicle movement, in particular:
reduces a high-pressure zone in the front portion of the housing;
promotes smooth distribution of the airflow along the upper surface of the housing;
reduces formation of turbulent zones in the rear portion of the housing;

As a result of said redistribution of the airflow, the lifting force acting on the housing during vehicle movement is reduced, and a downward aerodynamic force component directed toward the mounting surface is formed.

Providing the hinged supports with a fixed structural inclination angle of 26 degrees ensures constant contact of the magnets with the surface of the vehicle regardless of its geometry, thereby increasing mounting stability and reducing localized detachment loads.

Positioning the neodymium magnets in a rubberized casing increases the adhesion force to the metallic surface of the vehicle, reduces transmission of vibrations from the vehicle body to the device housing, and prevents damage to the vehicle surface.

The combination of the above features provides increased resistance of the housing to detachment and displacement during vehicle movement; reduction of the negative impact of aerodynamic loads on the mounting; stable positioning of the satellite communication terminal during operation in motion, including at increased speeds.

### For the Device—Step-By-Step Operating Instructions

Step 1. Assembly of the protective enclosure. The Adaptis protective enclosure for Starlink Mini, manufactured from 3 mm thick ABS plastic, consists of an upper cover and a lower base. To install the terminal, the enclosure is opened by separating its two parts.

The Starlink Mini terminal is placed inside the lower part of the enclosure into the designated mounting seat and centered along the internal contour. The geometry of the internal cavity matches the shape of the device and ensures a tight fit without play.

After positioning the terminal, the upper part is placed on top and aligned with the mounting holes. The enclosure parts are connected using screw fasteners, which are tightened sequentially in a cross pattern until fully secured.

After tightening, the enclosure forms a rigid monolithic structure that prevents displacement or vibration of the terminal during movement.

Step 2. Mounting the enclosure onto the supports. The assembled enclosure is installed onto four articulated supports (feet), which perform the functions of mounting and tilt angle adjustment.

The supports are attached to the enclosure at the corner zones through the provided mounting holes using screws and threaded inserts. Each support is secured by inserting the screw and tightening it with a tool until firmly clamped without play, while maintaining the ability for articulated rotation.

A pair of taller supports is installed on the side facing the direction of vehicle movement. A pair of shorter supports is installed on the opposite side.

This arrangement creates a stable tilt angle of the enclosure relative to the roof surface, reducing aerodynamic drag and improving the spatial orientation of the antenna.

Step 3. Surface preparation and base installation. Before installation, the vehicle roof surface must be cleaned of dust, moisture, and contaminants to ensure maximum magnetic contact with the metal.

The articulated stainless-steel supports are equipped with neodymium magnets located at the bottom of each foot.

The enclosure with attached supports is brought to the metal surface and positioned by vertically lowering it until the magnets contact the roof. Upon approaching the surface, the magnets automatically attract to the metal and self-secure.

For proper installation, the enclosure must be: aligned parallel to the vehicle's longitudinal axis; each support pressed individually with light hand pressure to ensure full contact.

As a result, a rigid magnetic connection between the enclosure and the surface is formed.

Step 4. Operation during movement. During vehicle movement, the system operates as a single monolithic structure.

The articulated architecture of the supports allows the feet to adapt to micro-irregularities of the surface and evenly distribute aerodynamic loads. This minimizes lift forces, reduces vibration, and ensures stable retention of the enclosure on the magnets even at high speeds.

The enclosure maintains a fixed tilt angle and spatial position without additional adjustment.

Step 5. Removal of the system from the vehicle. The device must be removed only in its fully assembled state.

For removal, grasp one edge of the enclosure by hand and perform a controlled lifting motion at an angle. This movement ensures the sequential detachment of the magnets from the surface, reducing the separation force.

Vertical removal with all magnets detached simultaneously is not recommended.

After complete separation from the surface, the enclosure is removed from the roof together with the supports as a single module.

Step 6. Disassembly of the adaptation enclosure. After removal, the enclosure is placed on a flat surface.

Using a tool, the screws securing the articulated supports are sequentially unscrewed, after which the supports are detached from the enclosure.

Next, the screws connecting the upper and lower parts of the enclosure are removed. The enclosure is opened, and the Starlink Mini terminal is taken out of the mounting seat.

While only certain features and embodiments of the disclosure have been illustrated and described, many modifications and changes may occur to those skilled in the art without materially departing from the novel teachings and advantages of the subject matter recited in the claims. The order or sequence of any process or method steps may be varied or re-sequenced according to alternative embodiments. It is, therefore, to be understood that the appended claims are intended to cover all such modifications and changes as fall within the true spirit of the disclosed embodiments. Furthermore, in an effort to provide a concise description of the exemplary embodiments, all features of an actual implementation may not have been described. It should be appreciated that in the development of any such actual implementation, as in any engineering or design project, numerous implementation specific decisions may be made. Such a development effort might be complex and time consuming, but would nevertheless be a routine undertaking of design, fabrication, and manufacture for those of ordinary skill having the benefit of this disclosure, without undue experimentation.

1. A mounting assembly for an internet terminal, the mounting assembly comprising:
a first surface,
a second surface bolted to the first surface forming a cavity between said surfaces, and
a plurality of hinged rubber-coated magnets connected to the second surface via thread elements and configured to change their distance from the second surface by moving along the thread elements.

2. The mounting assembly of claim 1, further comprising support elements, the support elements each located on the thread elements, such that the support elements are configured to support the weight of the mounting assembly.

3. The mounting assembly of claim 2, further comprising nut elements, the nut elements configured to mate with the thread elements and fix the distance of the plurality of hinged rubber-coated magnets from the second surface.

4. The mounting assembly of claim 1, wherein a longitudinal projection of the second surface has the shape of a triangle, and wherein a transverse projection of the second surface has the shape of a trapezoid.

5. The mounting assembly of claim 1, wherein the second surface comprises a hole for placement, fixation between the first and the second surfaces, and connection of an internet terminal.

6. The mounting assembly of claim 1, wherein the first surface and the second surface is made of plastic or a polymer.

7. The mounting assembly of claim 1, further comprising a plurality of galvanized metal plates connected to the plurality of hinged rubber-coated magnets and configured to be installed on aluminum, plastic roofs, and roofs with panoramic glass of a vehicle.

8. A magnetic transport mounting and protective housing for a satellite communication terminal comprising:
a protective housing having an upper and a lower surface, as well as front and rear portions;
four hinged supports rigidly connected to the housing in its corner regions; the hinged supports are divided into two pairs, wherein:
a first pair of supports is arranged at the front portion of the housing and has a greater structural height relative to the mounting surface of the vehicle;
a second pair of supports is arranged at the rear portion of the housing and has a smaller structural height relative to the mounting surface of the vehicle;
the difference in height between the front and rear supports forms an inclination of the housing relative to the vehicle mounting surface, whereby the upper surface of the housing is positioned at a predetermined angle relative to said surface; and
a magnet is secured to the lower part of each support and is housed in a casing.

9. The housing of claim 8, wherein the magnet is a neodymium magnet and the casing is a rubberized casing.

10. The housing of claim 8, wherein each hinged support is configured to allow angular deflection and has a fixed structural inclination angle of 26 degrees, providing adaptation to surfaces of complex geometry.

11. The housing of claim 8, the magnets are arranged such that all four supports simultaneously contact the mounting surface of the vehicle.

12. The housing of claim 8, wherein the housing is configured to accommodate a Starlink Mini terminal therein with fixation preventing displacement of the terminal during vehicle movement.

13. The housing of claim 8, wherein the protective housing is made of 3 mm thick ABS plastic.

14. The housing of claim 8, wherein the four hinged supports are made of stainless steel.
